(19) United States
(12) Patent Application Publication
(10) Pub. No.: US 2011/0090662 A1
(43) Pub. Date: Apr. 21, 2011

(54) METHOD AND APPARATUS FOR IMPROVING POWER NOISE OF BALL GRID ARRAY PACKAGE

(75) Inventors: Se-Young JANG, Seongnam-si (KR); Jeong-Ung KIM, Suwon-si (KR); Kun-Tak KIM, Suwon-si (KR)

(73) Assignee: SAMSUNG ELECTRONICS CO. LTD., Suwon-si (KR)

(21) Appl. No.: 12/905,639

(22) Filed: Oct. 15, 2010

(30) Foreign Application Priority Data
Oct. 15, 2009 (KR) 10-2009-0098152

(51) Int. Cl. H05K 1/18; H01L 21/52

(52) U.S. Cl. 361/782; 438/108; 257/E21.5

(57) ABSTRACT

An apparatus and method of improving power noise of a Ball Grid Array (BGA) package are provided. The method includes securing a space for a passive element mounting pad, on which a passive element can be mounted, adjacent to a power pad on a Printed Circuit Board (PCB) corresponding to a power pin of the BGA package, mounting the passive element on the passive element mounting pad, and mounting the BGA package at a position on the PCB, wherein the position on the PCB overlaps the passive element and further wherein the BGA package is mounted above the passive element.

### PRIORITY

This application claims the benefit under 35 U.S.C. §119(a) of a Korean patent application filed in the Korean Intellectual Property Office on Oct. 15, 2009 and assigned Serial No. 10-2009-0098152, the entire disclosure of which is hereby incorporated by reference.

### BACKGROUND OF THE INVENTION

1. Field of the Invention

The present invention relates generally to a method and a device for improving power noise of a Ball Grid Array (BGA) package. More particularly, the present invention relates to a method and a device for reducing power noise by minimizing a current path between a power pin and a decoupling capacitor of the BGA package.

2. Description of the Related Art

The degree of integration of a semiconductor Integrated Circuit (IC) has rapidly increased in conjunction with developments in the electronics industry. With increased integration, a package of the semiconductor IC has become larger, and the number of input/output pins of the semiconductor IC has exceeded several hundred. However, due to the recent trend of preference for slim electronic products, manufacturers have competed for fabricating a smaller package of the semiconductor IC. Accordingly, packaging technologies have been developed for accommodating more input/output pins in a smaller package of the semiconductor IC with easy automatic production using a chip mounter. One of the developed technologies is the packaging technology of a Ball Grid Array (BGA).

Generally, according to a standard type BGA package, a chip is mounted on a terminal board, and a plurality of solder balls having a certain diameter are arranged at regular intervals at a solder land positioned at a lower part of the terminal board. The solder balls may be mounted on a pad part for BGA packaging of a Printed Circuit Board (PCB).

Recently, electronic products such as a cell phone and a PC include the above-described BGA package performing various functions. For minimizing noise of power applied to the BGA package, a passive element (i.e., a decoupling capacitor) is arranged near the PCB where the BGA package is mounted.

FIG. 1A and FIG. 1B are a diagrams illustrating an arrangement of a passive element related to a BGA package according to the prior art.

Referring to FIG. 1A and FIG. 1B, a decoupling package 104 is arranged on the same plane 108 near a BGA package 102 or on an opposite surface 110 of a PCB 100 where a BGA component is arranged. The decoupling package 104 is provided for reducing the noise of power applied to the BGA package.

However, in the case that the decoupling capacitor 104 is arranged on the same plane near the BGA package 102, a physical distance between a power pin 106 in the BGA package 102 and the decoupling capacitor 104 is long so that a value of impedance is increased and thus the power noise is increased. On the contrary, in the case that the decoupling capacitor 104 is arranged on the opposite surface 110 of the PCB 100 where the BGA component is arranged, its placement on the back side of the PCB 100 limits use and arrangement of the PCB 100.

Therefore, a need exists for an improved method and apparatus for improving power noise of a BGA package.

### SUMMARY OF THE INVENTION

An aspect of the present invention is to address at least the above problems and/or disadvantages and to provide at least the advantages below. Accordingly, an aspect of the present invention is to provide a method and apparatus for improving power noise of a Ball Grid Array (BGA) package.

Another aspect of the present invention is to provide a method and apparatus for improving power noise of a BGA package implemented for reducing noise generated at a power pin by minimizing a physical distance from a passive element.

Another aspect of the present invention is to provide a method and a device for improving power noise of a BGA package implemented for efficiently reducing power noise with maximum space utilization of a Printed Circuit Board (PCB).

According to an aspect of the present invention, a method of improving power noise of a BGA package is provided. The method includes securing a space for a passive element mounting pad, on which a passive element can be mounted, adjacent to a power pad on a PCB corresponding to a power pin of the BGA package, mounting the passive element on the passive element mounting pad, and mounting the BGA package at a position on the PCB, wherein the position on the PCB overlaps the passive element and further wherein the BGA package is mounted above the passive element.

Also, the securing of the space for the passive element mounting pad may form a cavity at an upper surface of the PCB where the passive element mounting pad is positioned.

According to another aspect of the present invention, a device for improving power noise of a BGA package mounted on a PCB is provided. The device includes a passive element mounting pad for mounting a passive element adjacent to a power pad on the PCB corresponding to a power pin of the BGA package, a passive element mounted on the passive element mounting pad, and the BGA package mounted above the and overlapping the passive element and maintaining a separating gap from the passive element.

### BRIEF DESCRIPTION OF THE DRAWINGS

The above and other objects, features and advantages of certain exemplary embodiments of the present invention will be more apparent from the following description taken in conjunction with the accompanying drawings, in which:

FIG. 1A and FIG. 1B are a diagrams illustrating an arrangement of a passive element related to a BGA package according to the prior art;

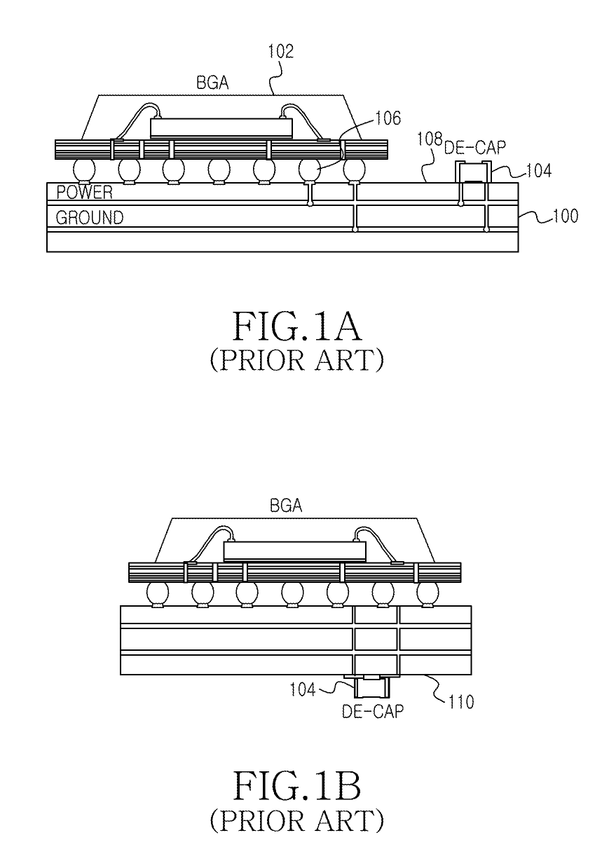

FIG. 2 is a cross-sectional view where a passive element related to a BGA package is arranged on a PCB according to an exemplary embodiment of the present invention;

FIG. 3 is a diagram illustrating a portion on a PCB where a BGA package and a related passive element are arranged according to an exemplary embodiment of the present invention;

FIG. 4 is a cross-sectional view illustrating an arrangement of a passive element related to a BGA package on a PCB according to an exemplary of embodiment of the present invention; and

FIG. 5 is a graph illustrating improvement of impedance according to change of position of a passive element according to an exemplary embodiment of the present invention.

Throughout the drawings, it should be noted that like reference numbers are used to depict the same or similar elements, features, and structures.

### DETAILED DESCRIPTION OF EXEMPLARY EMBODIMENTS

The following description with reference to the accompanying drawings is provided to assist in a comprehensive understanding of exemplary embodiments of the invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions may be omitted for clarity and conciseness.

The terms and words used in the following description and claims are not limited to the bibliographical meanings, but, are merely used by the inventor to enable a clear and consistent understanding of the invention. Accordingly, it should be apparent to those skilled in the art that the following description of exemplary embodiments of the present invention is provided for illustration purpose only and not for the purpose of limiting the invention as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

By the term “substantially” it is meant that the recited characteristic, parameter, or value need not be achieved exactly, but that deviations or variations, including for example, tolerances, measurement error, measurement accuracy limitations and other factors known to those of skill in the art, may occur in amounts that do not preclude the effect the characteristic was intended to provide.

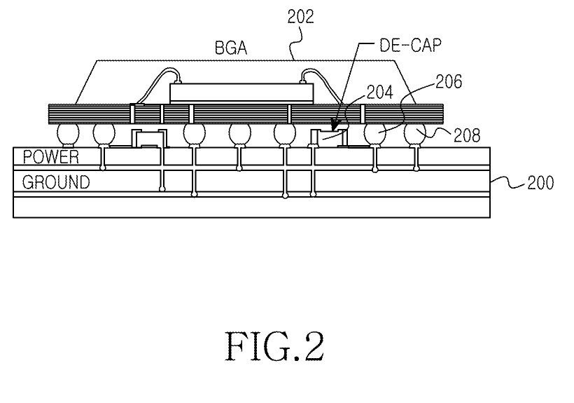

FIG. 2 is a cross-sectional view where a passive element related to a Ball Grid Array (BGA) package is arranged on a Printed Circuit Board (PCB) according to an exemplary embodiment of the present invention.

Referring to FIG. 2, the BGA package 202 is arranged on the PCB 200. Although not described in detail, the BGA package 202 has a known composition. For instance, a corresponding chip is mounted on a substrate where a certain pattern is formed, and a heat release means (i.e., heat sink) may be installed on its upper part. A plurality of solder balls 208 are organized to have regular intervals at solder lands positioned at a lower part of the substrate. Herein, the solder balls 208 may be mounted on a pad part for BGA package on the PCB 200.

For reducing power noise generated at a power pin of the BGA package 202, a passive element is mounted on the PCB 200. A known decoupling capacitor may be mounted as the passive element.

According to the present invention, the decoupling capacitor 204 is arranged near a power pin 206 under the BGA package 202. That is, the decoupling capacitor 204 is arranged at a position on the PCB 200 overlapped by the BGA package. In an exemplary implementation, a plurality of decoupling capacitors are arranged at regular intervals according to a size of the package and the number of power pins. Even though they are arranged in such a way, there is no interference between the BGA package 202 and the decoupling capacitor 204 because a height of the solder ball 208 of the BGA package 202 is higher than that of the decoupling capacitor 204. In this manner, a physical distance between the power pin 206 of the BGA package 202 and the decoupling capacitor 204 is shortened so that the power noise is reduced.

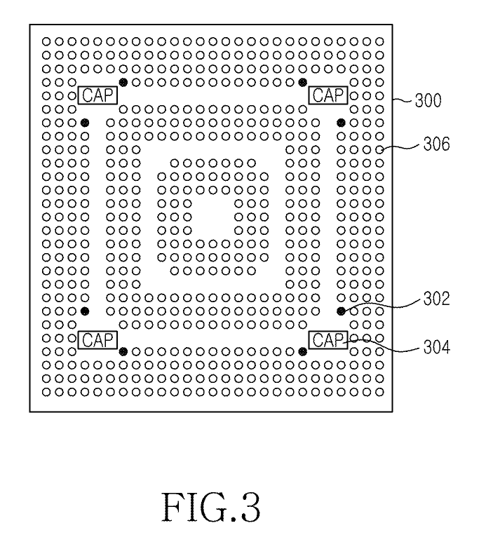

FIG. 3 is a diagram illustrating a portion on a PCB where a BGA package and a related passive element are arranged according to an exemplary embodiment of the present invention.

Referring to FIG. 3, a plurality of pads are arranged to correspond to the plurality of solder balls at positions on the mounting part 300 of the BGA package on the PCB. The plurality of pads include pads 306 for serving as input/output terminals corresponding to the BGA package chip, pads 302 for the power pin for supplying power to the BGA package, and a pad 304 for mounting the passive element arranged near the pad 302 for the power pin for reducing noise generated near the power pin of the BGA package. Notably, the pad 304 for mounting the passive element is arranged as close as possible to the power pin for reducing the noise by decreasing the physical distance. A decoupling capacitor may be used as the passive element and, preferably, mounted as a Surface Mounted Device (SMD) on the PCB.

Meanwhile, according to an exemplary embodiment of the present invention, a height of the passive element is made generally smaller than a diameter of the solder ball and the passive element is arranged among the solder balls of the BGA package. However, in the case that the height of the passive element is equal to or higher than the diameter of the solder ball, the arrangement at the position overlapped by the BGA package may be difficult.

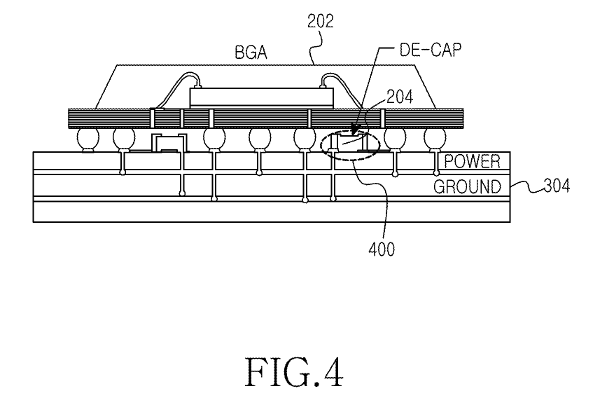

FIG. 4 is a cross-sectional view illustrating an arrangement of a passive element related to a BGA package on a PCB according to an exemplary embodiment of the present invention.

For addressing the above-mentioned problems regarding the height of the passive element and the height of the solder ball, as illustrated in FIG. 4, a cavity 400 may be formed at a portion of a PCB 304 where the decoupling capacitor 204 is mounted. Accordingly, the decoupling capacitor 204 may be mounted within the cavity 400. That is, using the cavity 400, the mounting space for the decoupling capacitor 204 under the BGA package 202 is increased. The cavity 400 may be formed during fabrication of the PCB such as by a laser or etching technique.

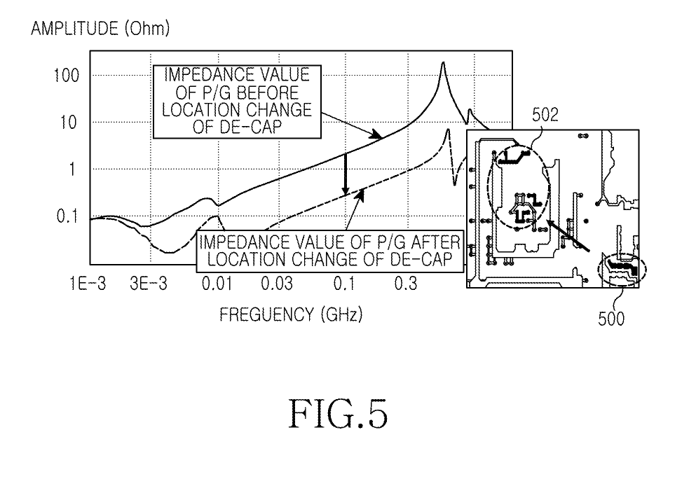

FIG. 5 is a graph illustrating improvement of impedance according to change of position of a passive element according to an exemplary embodiment of the present invention.

As illustrated in FIG. 5, the impedance value is reduced in the case (502) of arranging the decoupling capacitor at the overlapped position with the BGA package in comparison with the case (500) of arranging the decoupling capacitor at the outside of the BGA package.

Meanwhile, by using the above-described method for improving the power noise of the BGA package, the power noise of various electronic devices which use the BGA package may be improved.

According to exemplary embodiments of the present invention, the decoupling capacitor is arranged on the PCB at a lower portion overlapped by the BGA package, and thus the physical distance from the power pin is shortened so that the power noise of the BGA package can be reduced and the space for arranging another component on the PCB can be maximally utilized.

While the invention has been shown and described with reference to certain exemplary embodiments thereof, it will be understood by those skilled in the art that various changes in form and details may be made therein without departing from the spirit and scope of the invention as defined by the appended claims and their equivalents. Therefore, the scope of the invention is defined not by the detailed description of the invention but by the appended claims, and all differences within the scope will be construed as being included in the present invention.

What is claimed is:

1. A method of improving power noise of a Ball Grid Array (BGA) package, the method comprising:
securing a space for a passive element mounting pad, on which a passive element can be mounted, adjacent to a power pad on a Printed Circuit Board (PCB) corresponding to a power pin of the BGA package;
mounting the passive element on the passive element mounting pad; and
mounting the BGA package at a position on the PCB, and
wherein the position of the BGA package on the PCB overlaps a position of the passive element on the passive element mounting pad.

2. The method of claim 1, wherein the BGA package is mounted above the passive element.

3. The method of claim 1, wherein the securing of the space for the passive element mounting pad comprises arranging the space for the passive element mounting pad at an uppermost surface of the PCB corresponding to a lower surface of the BGA package.

4. The method of claim 3, wherein the securing of the space for the passive element mounting pad comprises forming a cavity with a certain depth at the uppermost surface of the PCB on which the passive element mounting pad is positioned, wherein the passive element is mounted within the cavity.

5. The method of claim 4, wherein the forming of the cavity comprises etching a portion of the PCB.

6. The method of claim 5, wherein the etching of the portion of the section of the PCB comprises using a laser.

7. The method of claim 4, wherein the certain depth of the cavity maintains a separating gap between the passive element and the BGA package.

8. The method of claim 1, wherein the mounting of the BGA package comprises arranging the BGA package to maintain a separating gap from the passive element.

9. The method of claim 1, wherein the passive element comprises a decoupling capacitor.

10. A device for improving power noise of a BGA package mounted on a PCB, the device comprising:
a passive element mounting pad for mounting a passive element adjacent to a power pad on the PCB corresponding to a power pin of the BGA package;
a passive element mounted on the passive element mounting pad; and
the BGA package mounted above and overlapping the passive element and maintaining a separating gap from the passive element.

11. The device of claim 10, wherein the passive element mounting pad is positioned at an upper surface of the PCB corresponding to a lower surface of the BGA package.

12. The device of claim 11, wherein the passive element mounting pad comprises a cavity having with a certain depth at the upper surface of the PCB.

13. The device of claim 12, wherein the cavity is formed by etching a portion of the PCB.

14. The device of claim 13, wherein the etching of the portion of the PCB is performed using a laser.

15. The device of claim 12, wherein the certain depth of the cavity maintains a separating gap between the passive element and the BGA package.

16. The device of claim 10, wherein the BGA package is mounted to maintain a separating gap from the passive element.

17. The device of claim 10, wherein the passive element comprises a decoupling capacitor.

18. The device of claim 10, wherein the device comprises a portable terminal.
